(19) United States
(12) Patent Application Publication
(10) Pub. No.: US 2007/0210348 A1
(43) Pub. Date: Sep. 13, 2007

(54) Phase-change memory device and methods of fabricating the same

(76) Inventors: JongHeui Song, Suwon-si (KR); Yong-Sun Ko, Suwon-si (KR); Jun Seo, Yongin-si (KR); Gyeo-Re Lee, Seoul (KR); Jae-Seung Hwang, Suwon-si (KR)

Correspondence Address: HARNESS, DICKEY & PIERCE, P.L.C., P.O. BOX 8910, RESTON, VA, 20195, US

(21) Appl. No.: 11/643,702

(22) Filed: Dec. 22, 2006

(30) Foreign Application Priority Data
Dec. 23, 2005 (KR) 10-2005-0128477

(51) Int. Cl. H01L 47/00

(52) U.S. Cl. 257/246; 257/4

(57) ABSTRACT

Example embodiments relate to a phase-change memory device and methods of fabricating the same. A phase-change memory device may include a lower electrode on a semiconductor substrate, a phase-change material layer on the lower electrode, a contact plug between the lower electrode and the phase-change material layer, wherein a first area of the contact plug in contact with a top of the lower electrode is greater than a second area of the contact plug in contact with a bottom of the phase-change material layer and an upper electrode on the phase-change material layer.

### PRIORITY STATEMENT

This application claims priority under 35 USC § 119 to Korean Patent Application No. 10-2005-0128477, filed Dec. 23, 2005, in the Korean Intellectual Property Office (KIPO), the entire contents of which are herein incorporated by reference.

### BACKGROUND

1. Technical Field

Example embodiments relate to a semiconductor, e.g. phase-change, memory device and methods of fabricating the same.

2. Discussion of Related Art

Semiconductor memory devices used for storing data may be divided into volatile memory devices and non-volatile memory devices. In a volatile memory device, for example, dynamic random access memory (DRAM) and/or static random access memory (SRAM), data input/output operation may be faster, but stored data may be lost when power is lost. A DRAM may have a periodical refresh operation and a higher electrical charge-storage capability. Research has been conducted to increase the capacitance of the DRAM device. For example, a method of increasing capacitance by increasing the surface area of a lower electrode of a capacitor may be used. In this method, the integration density of the DRAM device may decrease as the surface area of the lower electrode increases.

In a non-volatile memory device, for example, a NAND and/or NOR type flash memory based on electrically erasable programmable read only memory (EEPROM), stored data may be maintained even though power is lost. Non-volatile memory devices may have a gate pattern formed by stacking a gate insulating layer, a floating gate, a dielectric layer and/or a control gate on a semiconductor substrate. To record/erase data in/from a non-volatile memory device, a method of tunneling an electrical charge through the gate insulating layer may be used, and in this case, an operation voltage higher than a source voltage may be required. As a result, a flash memory device may have a voltage boosting circuit to form a desired voltage for recording/erasing data, and thus, an undesirable increased design rule.

According to the development of technologies in the field of information and communication and the popularization of information media, for example, computers, the demand has increased for a next-generation semiconductor memory device capable of higher speed operation, with a higher capacity memory-storage capability. The next-generation semiconductor device has been developed, combining the advantages of a volatile memory device, e.g., the DRAM, and those of a non-volatile memory device, e.g., the flash memory. The next-generation semiconductor device has advantages of lower power consumption upon driving, and improved characteristics of data retention capability and read/write operation. The next-generation semiconductor device may be a ferroelectric random access memory (FRAM), a magnetic random access memory (MRAM), a phase-change random access memory (PRAM) and/or a nano floating gate memory (NFGM).

Among the next-generation semiconductor memory devices, specifically, the PRAM (e.g., a phase-change memory device) may have a simpler structure and/or a higher integration density at a relatively inexpensive price and may be capable of higher-speed operation. Due to these merits, phase-change memory devices are becoming one of the most attractive next-generation semiconductor memory devices.

In a phase-change memory device, data may be stored using a resistance difference caused by a change of the crystal structure of a phase-change material layer. A chalcogenide compound (for example, GST: Ge—Sb—Te) including germanium (Ge), antimony (Sb) and tellurium (Te)) may be used as the phase-change material. The crystal structure of the phase-change material may vary depending on the intensity of a supplied current and the rate of supplying the current. After the phase-change material layer is heated at a temperature rising to about its melting point by applying a relatively high current pulse thereto for a shorter time, when the phase-change material layer is quenched (less than about 1 ns), the heated portion of the phase-change material layer may be in an amorphous state with a higher resistance (RESET).

After the phase-change material layer is crystallized by maintaining a crystallization temperature below the melting point by applying a relatively low current pulse thereto for a relatively long time, when the phase-change material layer is cooled, the heated portion of the phase-change material layer may be in a crystalline state with a lower resistance (SET).

As described above, the phase-change material layer has a feature that the extent of resistance varies depending on whether it is a crystal structure or an amorphous structure (essentially, the resistance may be lower in the crystalline state but may be higher in the amorphous state). Using this feature, data “1” or “0” may be programmed or erased. In the conventional art, there may be disclosed a structure of the phase-change memory device and a method of fabricating the same.

FIGS. 1A and 1B illustrate a sectional structure of a conventional phase-change memory device. In FIG. 1A, a lower electrode 12 may be formed on a p-type (or n-type) semiconductor substrate 10. A contact plug 16 penetrating an interlayer insulating layer 14 may be formed on the lower electrode 12. A phase-change material layer 18 and an upper electrode 20 may be formed on the contact plug 16.

After the temperature of the phase-change material layer 18 rises higher than the melting point (about 610C), the phase-change material layer 18 may be more rapidly quenched. A heated portion 22 of the phase-change material layer 18 may change into an amorphous state, such that a RESET (program) operation (of storing data “1”) may be performed.

After a temperature higher than the crystallization temperature but lower than the melting temperature is applied to the phase-change material layer 18 in the amorphous state, the phase-change material layer 18 may be slowly cooled. Referring to FIG. 1B, a heated portion 24 of the phase-change material layer 18 may change into a crystallization state, such that a SET (erase) operation (of storing data “0”) is performed.

In the phase-change memory device, a method of increasing current density by reducing the contact area between the contact plug 16 and the phase-change material layer 18 has been proposed, to decrease power consumption upon driving. The crystal structure of the phase-change material layer 18 may be changed by the Joule heat formed at the contact interface between the contact plug 16 and the phase-change material layer 18. The change in the crystal structure of the phase-change material layer 18 may be a phenomenon anticipated when the current is off, after the phase-change material layer 18 is heated to a predetermined or desired temperature by the Joule heat formed by the applied current per unit area.

To decrease the extent of the current required for changing the crystal structure of the phase-change material layer 18, there has been proposed a method of reducing the contact area between the contact plug 16 and the phase-change material layer 18. As the contact area is reduced, the size of the contact plug 16 formed between the lower electrode 12 and the phase-change material layer 18 may be reduced.

In the case of reducing the size of the contact plug 16, because the contact area between the contact plug 16 and the phase-change material layer 18 may become narrower, there may be effects of increasing the integration density and reducing the power consumption upon driving. As the size of the contact plug 16 is reduced, the contact area with the lower electrode 12 may also be reduced, which may result in a problem of decreasing an ohmic effect. The lower electrode 12 and the contact plug 16 may have an ohmic contact (resistive contact). As the contact interface between the lower electrode 12 and the contact plug 16 is narrower, the contact resistance may increase.

As a result, the current strength at the interface between the lower electrode 12 and the contact plug 16 may weaken (Current (I) varies inversely with resistance (R) and R varies inversely with the area (A)), which may eventually decrease the RESET/SET operational features of the phase-change memory device. Next-generation semiconductor memory devices having the advantages of a volatile memory device and those of a non-volatile memory device may be used in the field of information and communication, which has been developed, including personal computers, mobile phones, digital cameras, DVDs, MP3s, industrial vending machines, communication networks and/or electronic products.

Because the next-generation semiconductor memory devices has improved features (e.g., higher speed operation, higher capacity storage capability and/or lower power consumption), its applicable field may also be expanding. A phase-change memory device, among the next-generation semiconductor memory devices, may have a simpler structure and may be capable of providing a higher integration density at relatively inexpensive cost and higher-speed operation. Due to these advantages, the phase-change memory device has been widely used for mobile phones and personal digital assistants (PDAs).

FIG. 2 illustrates memory cell array of a phase-change memory device. In FIG. 2, phase-change memory cells (unit cell: UC) may be aligned in a matrix structure on m word lines WL0˜WLm-1 and n bit lines BL0˜BLn-1. A sense amplifier (not shown) may be positioned in each bit line.

FIG. 3 illustrates a structure of a phase-change memory cell forming the memory cell array. In FIG. 3, the word line may be connected with a gate of the phase-change memory cell UC, and the bit line may be connected with a variable resistor C of the phase-change memory cell UC. The variable resistor C may include a GST layer, and an upper electrode may be connected to a bit line BL through a bit line contact (not shown).

In the variable resistor C, including the phase-change material layer, its crystal structure may vary according to an amount of current to be supplied and a time of supplying the current. When an access transistor M is turned on and a current path is formed from the bit line BL to the ground voltage, the current may be supplied to the variable resistor C including the phase-change material layer.

FIG. 4 illustrates change curves of the crystal structure of a phase-change material layer employed in the phase-change memory cell, with respect to temperature and time. In FIG. 4, the phase-change material layer may be heated at a temperature higher than a melting temperature Tm (about 610° C.) for time T1 by supplying the current to the phase-change material layer. When the phase-change material layer is more rapidly quenched, it may change into an amorphous state with an irregular crystal structure (line L1). This is in a program state, e.g., in a RESET state, where data “1” is stored.

The phase-change material layer may be heated at a temperature higher than the crystallization temperature Tc (about 450° C.) but lower than the melting temperature Tm (about 610° C.), for time T2 which is longer than T1. When the phase-change material layer is slowly cooled, it may change into a crystalline state with a regular crystal structure (line L2). This is in an erase state, e.g., in a SET state, where data “0” is stored.

When the crystal structure of the phase-change material layer changes, the relative resistance of the phase-change material layer changing into the amorphous state may be greater than that of the phase-change material layer changing into the crystalline state. A READ operation may sense data “1” or “0” by a voltage difference according to the current flowing through the variable resistor C including the phase-change material layer.

In the phase-change memory device with the aforementioned operation characteristics, the size of the contact plug positioned between the phase-change material layer and the lower electrode may be reduced to decrease power consumption upon driving. As a result, the power consumption may decrease. The contact resistance at the contact interface between the lower electrode and the contact plug may not be freely controlled because the contact area between the lower electrode and the contact plug may also be reduced.

### SUMMARY

Example embodiments are directed to a phase-change memory device capable of increasing the contact area between a lower electrode and a contact plug, and to methods of fabricating the same. Example embodiments relate to a phase-change memory device capable of improving an ohmic contact effect by reducing the contact resistance between a lower electrode and a contact plug, and methods of fabricating the same. Example embodiments relate to a phase-change memory device capable of improving the RESET/SET operational features, and methods of fabricating the same.

In accordance with example embodiments, a phase-change memory device may include a lower electrode formed on a semiconductor substrate, a phase-change material layer formed on the lower electrode, a contact plug formed between the lower electrode and the phase-change material layer, wherein a contact area between the contact plug and a top of the lower electrode is larger than a contact area between the contact plug and a bottom of the phase-change material layer and an upper electrode formed on the phase-change material layer.

In example embodiments, a method of fabricating a phase-change memory device may include forming a lower electrode on a semiconductor substrate, forming an interlayer insulating layer on the lower electrode, forming a contact plug penetrating the interlayer insulating layer and having a sectional area of a bottom region thereof being greater than that of a top region thereof, forming a phase-change material layer on the contact plug and forming an upper electrode.

Forming the contact plug may include forming an etch mask pattern on the interlayer insulating layer, performing an etch process with respect to the interlayer insulating layer exposed by the etch mask pattern and forming a contact plug hole for exposing the lower electrode and filling the contact plug hole.

In accordance with example embodiments, a method of fabricating a phase-change memory device may include forming a lower electrode on a semiconductor substrate, vapor-depositing a first interlayer insulating layer on the lower electrode and a second interlayer insulating layer having an etch selectivity with respect to the first interlayer insulating layer, forming a first contact hole for exposing the first interlayer insulating layer, by performing a first etch process with respect to the second interlayer insulating layer, forming a second contact hole, with its horizontal distance greater than that of the first contact hole, for exposing the lower electrode, by performing a second etch process with respect to the first interlayer insulating layer exposed by the first contact hole, forming a contact plug for supplying a current, by filling the first and second contact holes with a conductive material and forming a phase-change material layer and an upper electrode on the contact plug.

As a result, a current density may increase with respect to the phase-change material layer in contact with the contact plug, thereby decreasing, e.g. reducing or minimizing, power consumption upon driving. Also, an ohmic contact effect may be improved at a contact interface between the bottom area of the contact plug and the lower electrode, thereby improving the RESET/SET operation characteristics of the phase-change memory device. Due to the structural feature of the contact plug that the bottom area is greater than the top area, the contact plug may be secured between the interlayer insulating layers. This feature may alleviate the problem that a conductive material forming the contact plug may become loose or break away by subsequent processes or external physical forces.

### BRIEF BESCRIPTION OF THE DRAWINGS

Example embodiments will be more clearly understood from the following detailed description taken in conjunction with the accompanying drawings. FIGS. 1A-7C represent non-limiting, example embodiments as described herein.

FIGS. 1A and 1B are diagrams illustrating a sectional structure of a conventional phase-change memory device;

FIG. 2 is a diagram illustrating a conventional memory cell array of a phase-change memory device;

FIG. 3 is a diagram illustrating the structure of a conventional phase-change memory cell forming the memory cell array;

FIG. 4 is a conventional diagram illustrating change curves of the crystal structure of a phase-change material layer employed in the phase-change memory cell, with respect to temperature and time;

FIG. 5 is a diagram illustrating a sectional structure of a phase-change memory device according to example embodiments;

FIGS. 6A-6H are diagrams illustrating sectional views sequentially illustrating a method of fabricating a phase-change memory device according to example embodiments; and

FIGS. 7A-7C are diagrams illustrating sectional views sequentially illustrating a method of fabricating a phase-change memory device according to example embodiments.

FIGS. 8A-8F are diagrams illustrating shapes of a contact plug according to example embodiments.

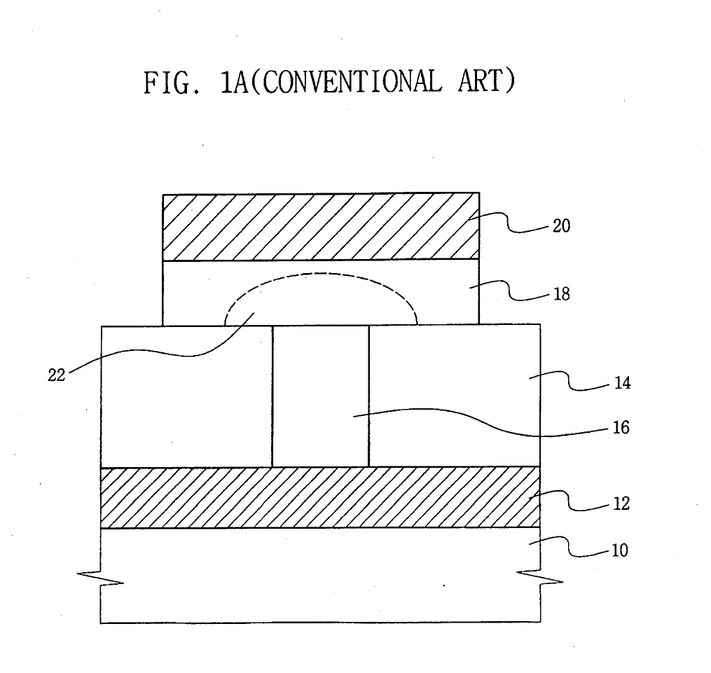

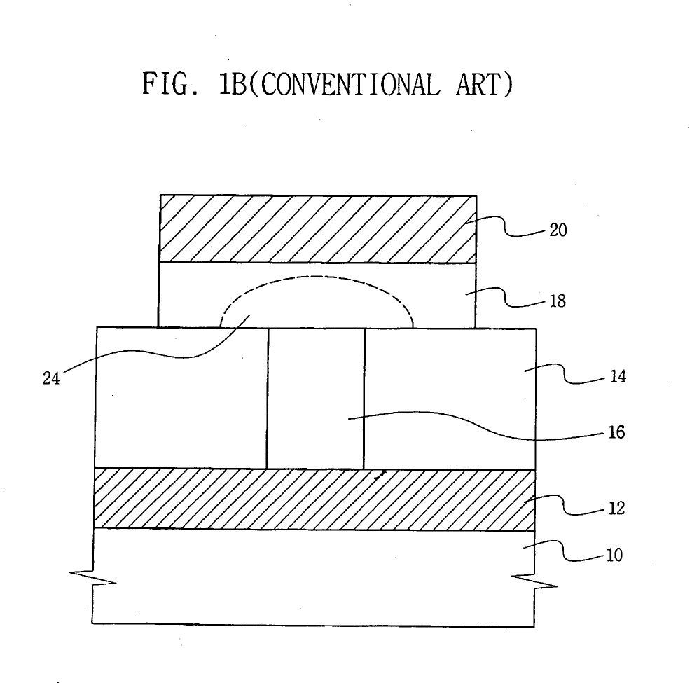

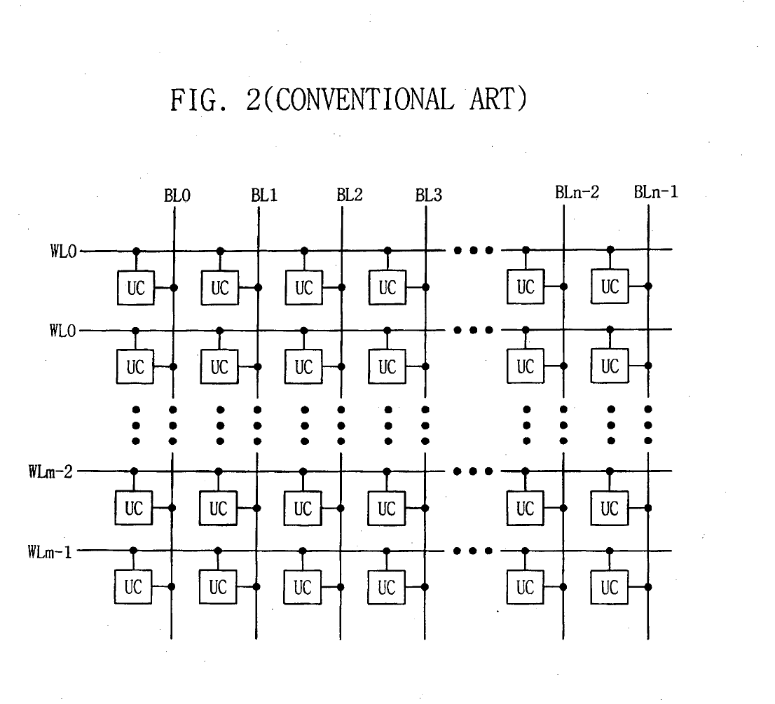

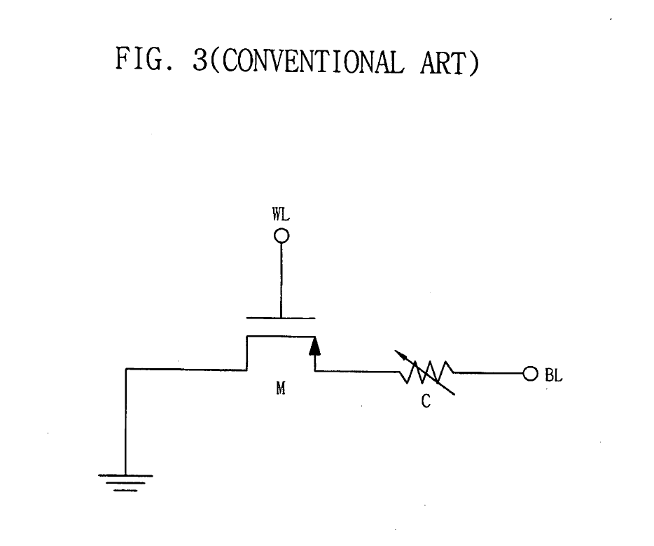

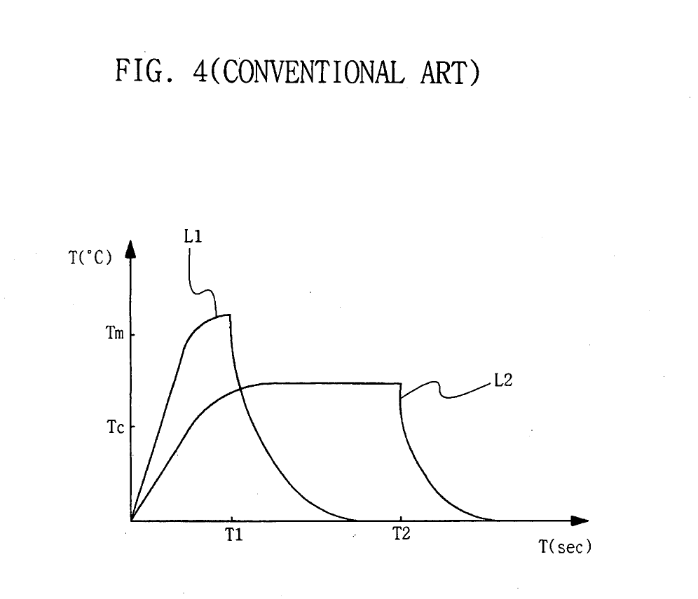

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative example embodiments are disclosed herein. Specific structural and functional details disclosed herein are merely representative for purposes of describing example embodiments. Example embodiments may, however, be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of example embodiments. Like numbers refer to like elements throughout the description of the figures.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Also, the use of the words “compound,” “compounds,” or “compound(s),” refer to either a single compound or to a plurality of compounds. These words are used to denote one or more compounds but may also just indicate a single compound.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of example embodiments.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects of example embodiments will be described in detail with reference to the attached drawings. However, example embodiments are not limited to those described.

Example embodiments relate to a semiconductor, e.g. phase-change, memory device and methods of fabricating the same. Example embodiments provide a phase-change memory device which is capable of reducing or minimizing the power consumption upon driving, increasing or maximizing an ohmic contact effect between the lower electrode and the contact plug, freely controlling the contact resistance between the lower electrode and the contact plug and/or improving RESET/SET operational features, and a method of fabricating the same.

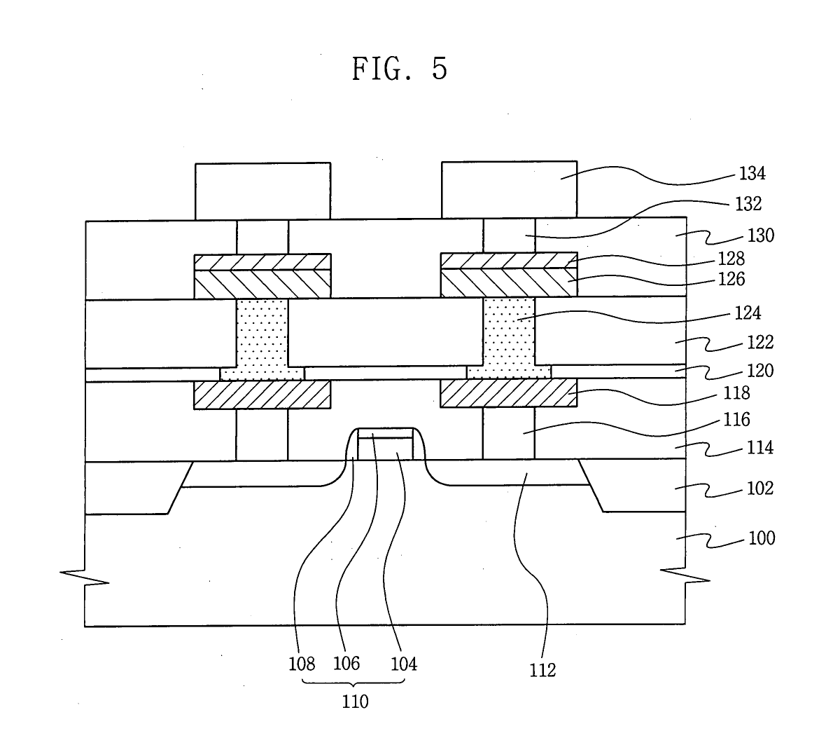

The phase-change memory device and the method of fabricating the same according to example embodiments will be described in detail, with reference to FIGS. 5, 6A-6H, and 7A-7C. FIG. 5 is a diagram illustrating a sectional structure of a phase-change memory device according to example embodiments.

Referring to FIG. 5, a gate region 110 including a conductive layer 104, a barrier layer 106 and a sidewall spacer 108 may be formed on a semiconductor substrate 100 which may be generally divided into an active region and a field area by a shallow trench isolation layer 102. The conductive layer 104 may be composed of polysilicon and/or a dual structure of polysilicon and silicide. Source/drain regions 112 may be formed between the gate region 110 and the trench isolation layer 102 by ion implantation of impurities (boron (B) of Group III and/or phosphorous (P) or arsenic (As) of Group V). A contact 116 and a lower electrode 118 may be formed on the source/drain regions 112.

The contact 116 and the lower electrode 118 may be surrounded by a first interlayer insulating layer 114. A contact plug 124 penetrating an oxide layer 120 and a nitride layer 122 may be formed on the lower electrode 118. A phase-change material layer 126 and an upper electrode 128 surrounded by a second interlayer insulating layer 130 may be formed on the contact plug 124. The upper electrode 128 may be connected with a metal wiring 134 through a via contact 132.

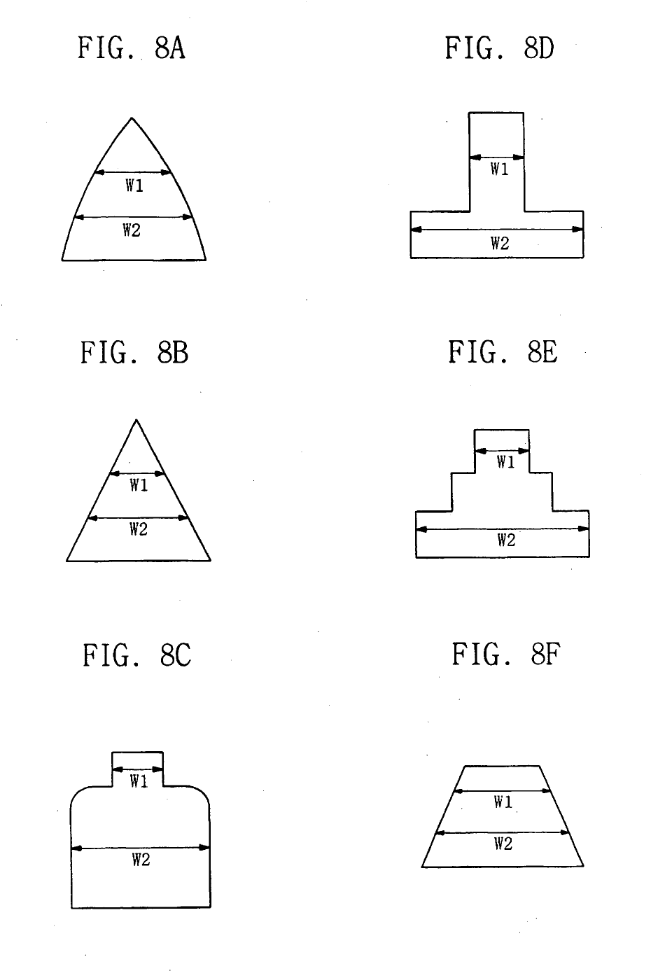

FIGS. 8A-8F are diagrams illustrating shapes of a contact plug according to example embodiments. The contact plug 124 connecting the lower electrode 118 and the phase-change material layer 126 may be the core constitution of the phase-change memory device according to example embodiments. A top area of the contact plug 124, which contacts the phase-change material layer 126, may be formed to be relatively smaller than a bottom area of the contact plug 124, which contacts the lower electrode 118 (for example, the contact plug 124 may have a double-spacer shape as illustrated in FIG. 8A, a conical shape as illustrated in FIG. 8B and/or a bottle-like shape as illustrated in FIG. 8C in which a width W₁ of a top area is smaller than a width W₂ of a bottom area, a tiered: [symbol] shape as illustrated in FIG. 8D, step shape as illustrated in FIG. 8E or a trapezoidal shape as illustrated in FIG. 8F). The top area of the contact plug 124 may secure a higher current density, thereby forming an area (about 50 nm) to reduce or minimize the power consumption upon driving. The bottom area of the contact plug 124 may be formed to further improve an ohmic contact effect at the contact interface between the bottom area of the contact plug 124 and the lower electrode 118.

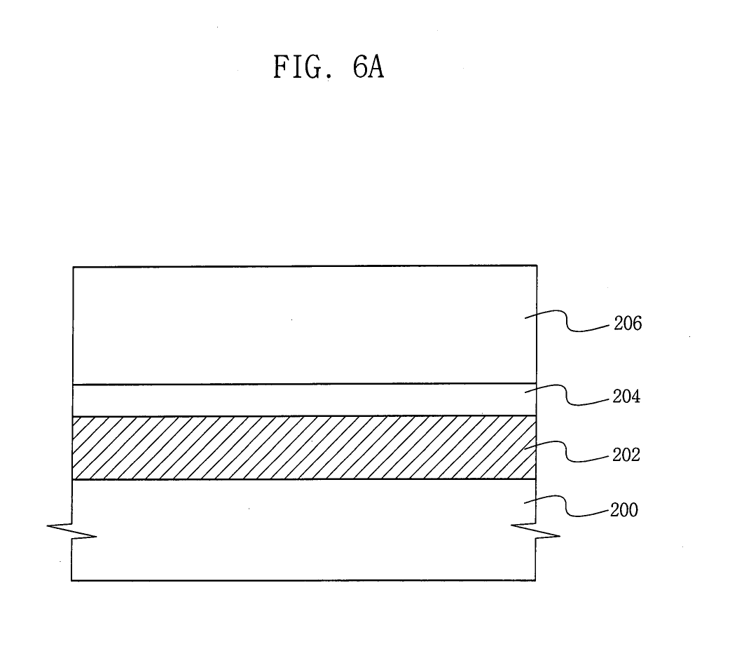

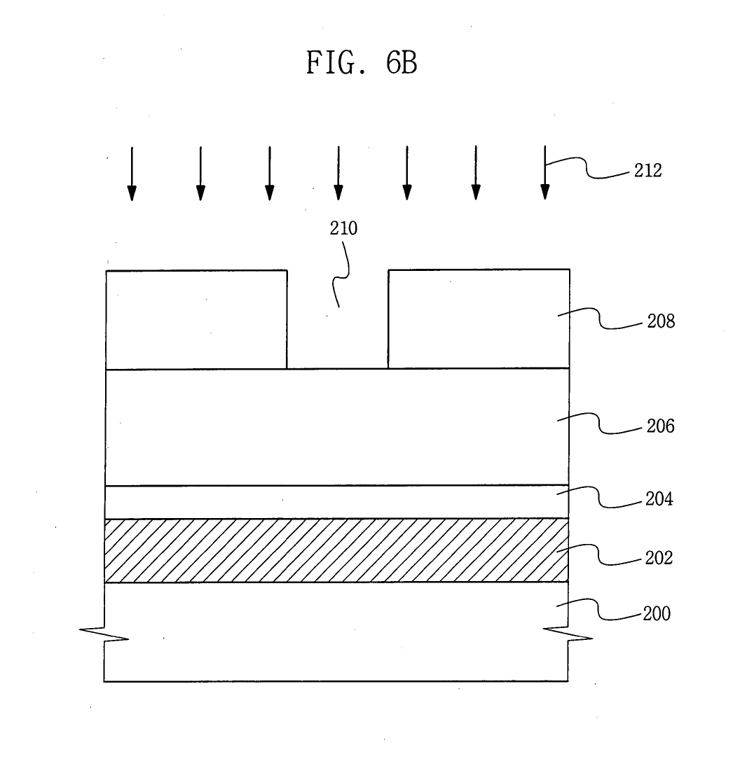

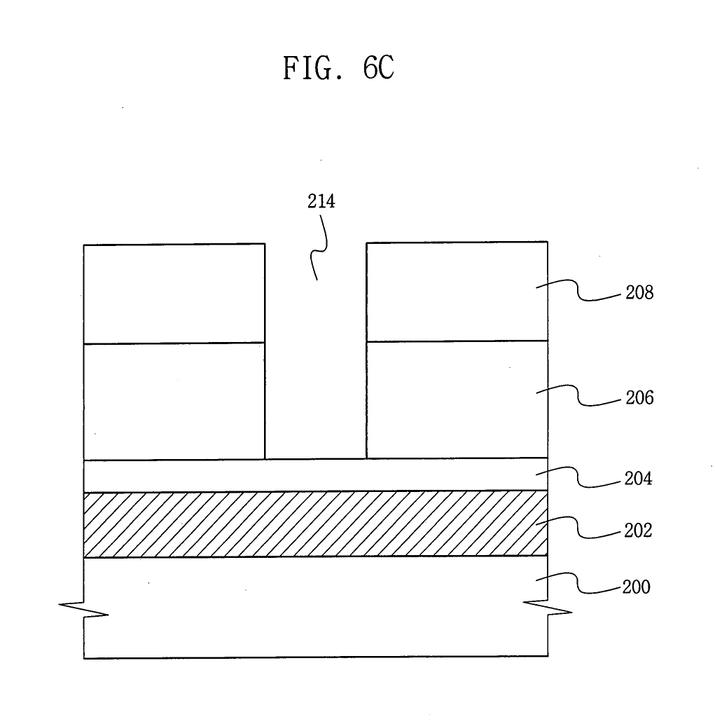

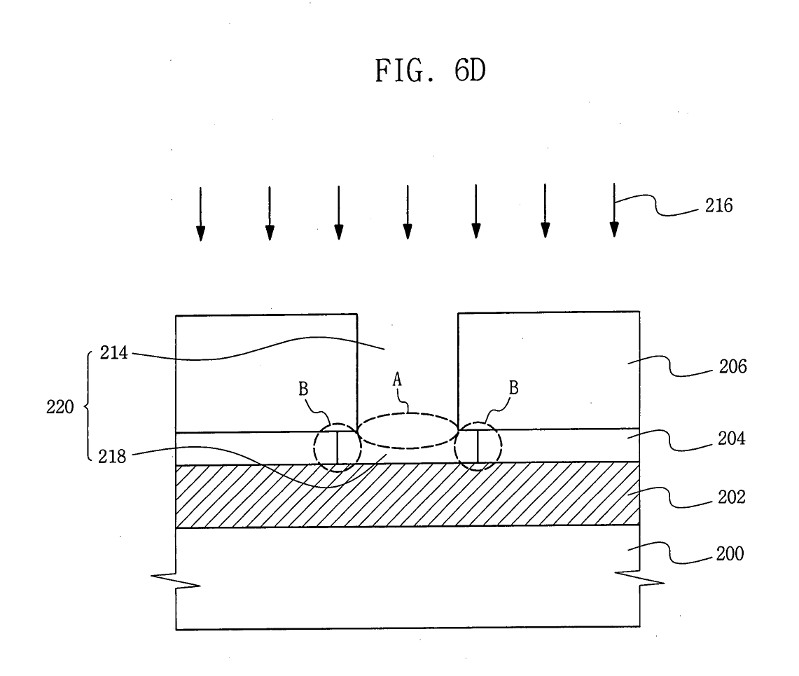

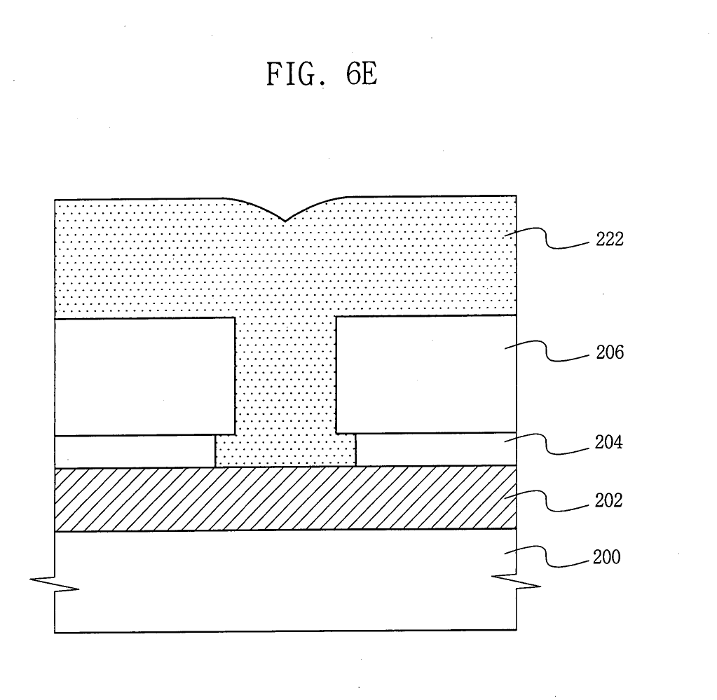

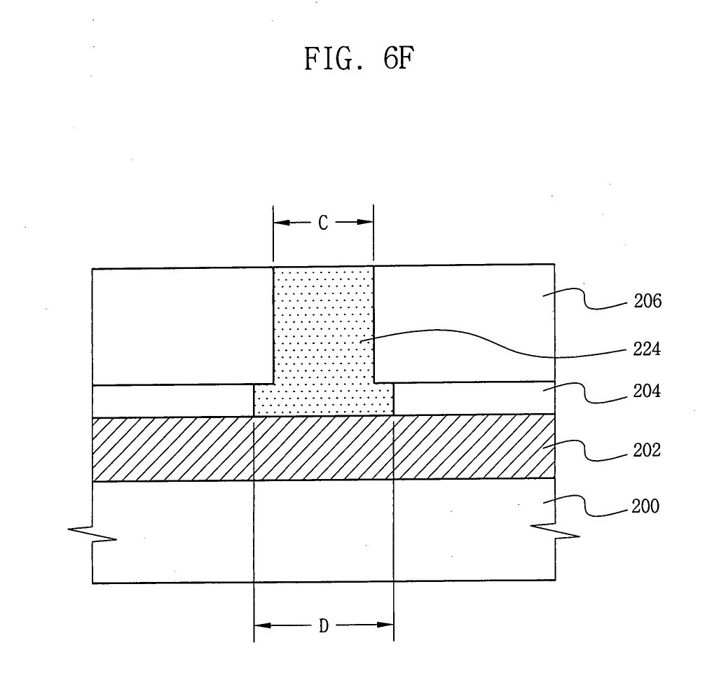

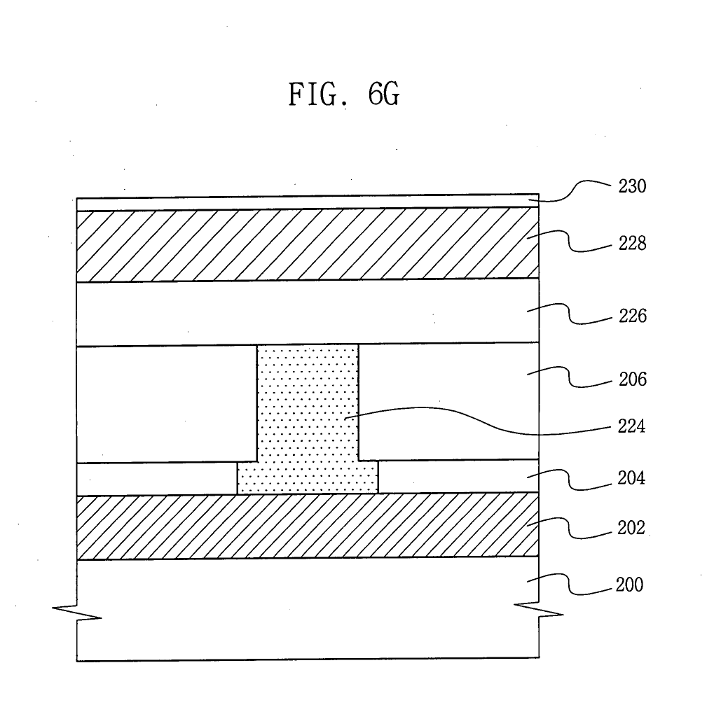

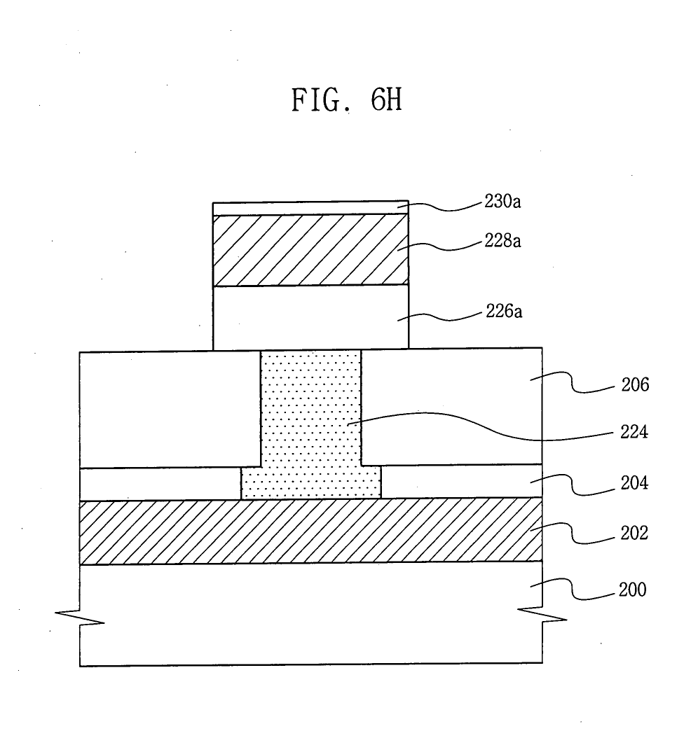

A method of fabricating a contact plug of a phase-change memory device according to example embodiments will be described, with reference to FIGS. 6A-6H, below. In FIG. 6A, a lower electrode 202 may be formed on a p-type semiconductor substrate 200 doped with Group III impurities, e.g., boron (B) and/or an n-type semiconductor substrate doped with Group V impurities, e.g., phosphorous (P) and/or arsenic (As). The lower electrode 202 may be composed of, for example, a tungsten layer.

A first interlayer insulating layer 204 may be deposited, for example, with a thickness of about 50 Å˜about 500 Å, on the lower electrode 202. The first interlayer insulating layer 204 may be composed of an oxide layer, for example, silicon (IV) oxide (SiO₂), high temperature oxide (HTO), middle temperature oxide (MTO), middle temperature oxide-nitride-oxide (MTON₂O), tetraethoxysilane (TEOS), undoped silicate glass (USG), spin-on-glass (SOG) and/or high density plasma oxide (HDPO). A second interlayer insulating layer 206 may be deposited, for example, with a thickness of about 500 Å˜about 950 Å, on the first interlayer insulating layer 204. The second interlayer insulating layer 206 may be a material layer having an etch selectivity with respect to the first interlayer insulating layer 204, and may be composed of, for example, a nitride layer (e.g., silicon nitride (Si₃N₄)). According to pressure, temperature, applied energy and air pressure, the first and second interlayer insulating layers 204 and 206 may be deposited by an atmospheric pressure chemical vapor deposition (APCVD) process performed under an atmospheric pressure, a low pressure chemical vapor deposition (LPCVD) process performed under a low pressure atmosphere, and a plasma enhanced chemical vapor deposition (PECVD) process performed under a plasma ambient.

In FIG. 6B, a photo mask pattern 208 for etching the second interlayer insulating layer 206 may be formed on the second interlayer insulating layer 206. The photo mask pattern 208 may be formed through exposure and development processes after a positive and/or negative type photoresist may be applied on the second interlayer insulating layer 206. A horizontal distance of a hole 210 between adjacent photo mask patterns 208 may be about 50 nm or less, to reduce the power consumption upon driving.

A dry etch process 212 may be performed on the second interlayer insulating layer 206, by using the photo mask pattern 208 as a self-aligned etch mask. The dry etch process 212 may be performed using gas plasma, ion beam and/or sputtering. When gas plasma is used, the pressure inside a process chamber may be, for example, about 35 mT, and the radio frequency (RF) power may be maintained at about 400 W. The etch process may be performed for about 57 seconds by injecting difluoromethane (CH₂F₂) (about 20 standard cubic centimeters per minute (SCCM)), Oxygen (O₂) (about 20 SCCM) and Argon (Ar) (about 180 SCCM) into the process chamber.

FIG. 6C is a diagram illustrating the results of the dry etch process 212. The dry etch process 212 may have anisotropic etching characteristics. As shown in FIG. 6C, the second interlayer insulating layer 206 exposed by the hole 210 of the photo mask pattern 208 may be vertically etched downward, thereby forming a first contact hole 214 exposing the first interlayer insulating layer 204. The horizontal distance of the first contact hole 214 may be about 50 nm or less according to the horizontal distance of the hole 210 of the photo mask pattern 208 used as the etch mask upon the dry etch process 212.

Referring to FIG. 6D, an ashing process may be performed with respect to the semiconductor substrate 200 where the first contact hole 214 is formed, to cleanly remove the photo mask pattern and by-products resulting from the etch process. A wet etch process 216 may be performed to etch the first interlayer insulating layer 204 exposed by the first contact hole 214. During the wet etch process 216, the pressure inside the process chamber may be, for example, about 40 mT, and the RF power may be maintained at about 45 W.

The wet etch process may be performed for about 30 seconds, using tetrafluoromethane (CF₄) (about 80 SCCM) and (Oxygen) O₂ (about 20 SCCM) as etchants. The wet etch process 216 may have isotropic etching characteristics. When the wet etch process 216 is performed, the etch may progress with respect to not only the portion (marked as A) of the first interlayer insulating layer 204 exposed by the first contact hole 214 but also the portion (marked as B) of the first interlayer insulating layer 204 below the second interlayer insulating layer 206.

Generally, because the wet etch process using a wet etchant is an isotropic etch process, a horizontal length and a vertical length of an etching target layer may be etched at the same rate. When the wet etch process 216 is performed with respect to the first interlayer insulating layer 204, the etching may progress with respect to the lower portion B below the second interlayer insulating layer 206 at the same length as the thickness of the portion A exposed by the first contact hole 214 and etched. The undercut etching may progress, such that the portion of the first interlayer insulating layer 204 below edges of the second interlayer insulating layer 206 exposed by the first contact hole 214 may be further etched. As a result, a second contact hole 218 having a horizontal distance greater than that of the first contact hole 214 may be formed under the first contact hole 214. The first and second contact holes 214 and 218 may constitute a contact plug hole 220. The contact plug hole 220 may be filled with a conductive material through a subsequent process, thereby forming a contact plug for electrically connecting the lower electrode 202 and the phase-change material layer (not shown), e.g., a contact plug capable of acting as a node for applying a current to the phase-change material layer.

FIG. 6E is a diagram illustrating a process of filling the inside of the contact plug 220 with a conductive material. In FIG. 6E, an isotropic etch process may be performed to remove the surface of the lower electrode 202 damaged during the dry etch process 212 for forming the first contact hole 214 and the wet etch process 216 for forming the second contact hole 218 may be performed. The isotropic etch process may be an additional process to remove a damaged layer of the surface of the lower electrode 202. When the lower electrode 202 includes tungsten, the isotropic etch process for removing the damaged layer may be essentially performed, and CF₄, nitrogen trifluoride (NF₃) and O₂ may be used as an etchant. When the isotropic etch process is performed, the surface of the lower electrode 202 may have a depressed shape (not shown) because it may be isotropically etched at a desirable thickness.

After the damaged layer of the surface of the lower electrode 202 is removed through the isotropic etch process, a conductive material 222 may be deposited on the entire surface of the semiconductor substrate 200. As a result, the conductive material 222 may fill the inside of the contact plug hole 220. The conductive material 222 may be doped polysilicon, tungsten, aluminum, tantalum and/or copper.

In FIG. 6F, a surface planarization process (e.g., an etch-back process and/or a chemical mechanical polishing (CMP) process) may be performed with respect to the semiconductor substrate 200 where the conductive material 222 is deposited. As a result, the conductive material positioned on the second interlayer insulating layer 206 may be removed, except for the conductive material filling the inside of the contact plug hole 220, thereby forming a contact plug 224 in a tiered ( [symbol] ) and/or step shape (or a double-spacer, trapezoidal, bottle-like and/or a conical shape in which the width W₁ of a top area is smaller than the width W₂ of a bottom area).

As shown in FIG. 6F, the contact plug 224 in the tiered ( [symbol] ) and/or step shape (or a double-spacer, trapezoidal, bottle-like and/or a conical shape) with a horizontal distance D of its bottom area may be relatively greater than a horizontal distance C of its top area is the core constitution in the phase-change memory cell, according to example embodiments. In example embodiments, the horizontal distance C of the top area of the contact plug 224 may be about 50 nm. The horizontal distance D of the bottom area thereof may vary according to the deposition thickness of the first interlayer insulating layer 204. When the first interlayer insulating layer 204 is formed with the thickness of about 10 Å based on the formula of “1 nm=10 Å”, the horizontal distance D of the bottom area of the contact plug 224 may be about 52 nm (because it increases at both sides, right and left, by about 1 nm laterally, respectively). When the first interlayer insulating layer 204 is deposited with a thickness of about 50 Å˜about 500 Å, the horizontal distance D of the bottom area of the contact plug 224 may vary within the range of about 60 nm˜about 150 nm. The horizontal distance D of the bottom area may be formed so as to be greater than the horizontal distance C of the top area, by twice the thickness of the first interlayer insulating layer 204.

In realizing the phase-change memory device, when the contact area between the phase-change material layer and the contact plug is less and the contact area between the lower electrode and the contact plug is greater, the electrical characteristics of the phase-change memory device may be improved. When the current is applied to the phase-change material layer through the contact plug, if the contact interface between the phase-change material layer and the contact plug is smaller, the current density applied to the phase-change material layer may increase and the power consumption may be reduced upon driving.

The contact plug and the lower electrode may form the ohmic contact (resistive contact). When the contact interface between the contact plug and the lower electrode is narrower, it may be difficult to control the contact resistance. As in example embodiments, the contact interface between the contact plug and the lower electrode may increase by forming the horizontal distance of the bottom area of the contact plug so as to be relatively greater than that of the top area thereof, thereby more easily controlling the contact resistance (so that the ohmic contact effect is improved). Consequently, the RESET and SET operation characteristics of the phase-change memory device may be improved.

Referring to FIG. 6G, a phase-change material layer 226 may be deposited on the semiconductor substrate 200 where the contact plug 224 is formed. The phase-change material layer 226 may be composed of one or more materials selected from the group including germanium (Ge), antimony (Sb), tellurium (Te), selenium (Se), bismuth (Bi), lead (Pb), tin (Sn), arsenic (As), sulfur (S), silicon (Si), phosphorus (P), oxygen (O) and/or a mixture or alloy thereof. For example, a chalcogenide compound (GST or Ge—Sb—Te) including germanium (Ge), antimony (Sb) and tellurium (Te) may be used as the phase-change material. In addition to the GST, other chalcogenide compounds that may be used as the phase-change material are As—Sb—Te, As—Gb—Te, As—Gb—Sb—Te, Sn—Sn—Te, In—Sn—Sn—Te (where In: indium), Ag—In—Sb—Te (where Ag: silver), Group VB element (Ta, niobium (Nb), vanadium (V))—Sb—Te, Group VB element (Ta, Nb, V)—Sb—Se, Group VIB element (tungsten (W), molybdenum (Mo), chromium (Cr))—Sb—Te and/or Group VIB element (W, Mo, Cr)—Sb—Se. The compounds may be used by further adding nitrogen. The phase-change material layer 226 may be formed having a thickness of about 100 Å˜about 1000 Å at a temperature of about 100° C.˜about 300° C.

A conductive layer 228 for an upper electrode may be formed on the phase-change material layer 226. The conductive layer 228 may be composed of a conductive material including nitrogen, metal, dual layer of metal and metallic silicide, alloy, metallic oxynitride and/or a conductive carbon compound. For example, the conductive layer 228 may have the conductive material including a nitrogen element, e.g., titanium nitride (TiN), tantalum nitride (TaN), tungsten nitride (WN), molybdenum nitride (MoN), Niobium nitride (NbN), titanium silicon nitride (TiSiN), titanium aluminum nitride (TiAIN), titanium boron nitride (TiBN), zirconium silicon nitride (ZrSiN), tungsten silicon nitride (WSiN), tungsten boron nitride (WBN), zirconium aluminum nitride (ZrAIN), molybdenum silicon nitride (MoSiN), molybdenum aluminum nitride (MoAIN), tantalum silicon nitride (TaSiN), tantalum aluminum nitride (TaAIN), and/or the conductive material layer may include any one selected from the group including titanium (Ti), tungsten (W), molybdenum (Mo), tantalum (Ta), titanium silicide (TiSi), tantalum silicide (TaSi), titanium-tungsten (TiW), titanium oxynitride (TiON), titanium aluminum oxynitride (TiAION), tungsten oxynitride (WON), tantalum oxynitride (TaON) and/or a combination thereof. An oxide layer 230 (e.g., SiO₂, HTO, MTO, MTON₂O, TEOS, USG, SOG and/or HDPO) may be deposited on the conductive layer 228.

In FIG. 6H, a general photolithography process may be performed to form an oxide layer pattern 230a. The conductive layer 228 and the phase-change material layer 226 may be etched, using the oxide layer pattern 230a as the etch mask. As a result, a phase-change material layer 226a and an upper electrode 228a may be formed on the plug pattern 224. Although not shown, a capping layer and a via contact for connecting the bit line may be formed on the resultant structure, and a metallization process may be performed, thereby completing the phase-change memory device.

A method of fabricating the phase-change memory device, according to example embodiments, has been described with reference to FIGS. 6A-6H.

In a conventional phase-change memory device, the contact area between the phase-change material layer and the contact plug may be reduced to decrease the power consumption upon driving, thereby increasing the current density applied to the phase-change material layer and decreasing the power consumption upon driving. As the size of the contact plug reduces, the contact area between the lower electrode and the contact plug may also reduce. This may make it difficult to accurately control the contact resistance between the lower electrode and the contact plug, thereby decreasing the RESET/SET operation characteristics of the phase-change memory device.

To solve the aforementioned problems of the conventional phase-change memory device, example embodiments may utilize the contact plug 224 in the tiered ( [symbol] ) or step shape (or a double-spacer, trapezoidal, bottle-like and/or a conical shape), in which the contact area between the contact plug 224 and the lower electrode 202 may be formed to be relatively greater than the contact area between the contact plug 224 and the phase-change material layer 226a. The top area of the contact plug 224, which has the horizontal distance C and contacts with the phase-change material layer 226a, may be formed so as to maintain a higher current density and to have an area (about 50 nm) to reduce or minimize the power consumption upon driving. The bottom area of the contact plug 224, which has the horizontal distance D and contacts with the lower electrode 202, may be formed so as to have an area to improve the ohmic contact effect between the contact plug 224 and the lower electrode 202, within a range of causing nominal process error (in other words, a void may be formed when the conductive material fills the inside of the contact plug hole to form the contact plug). As a result, a higher current density may be maintained at the contact interface between the contact plug 224 and the phase-change material layer 226a, thereby reducing the power consumption upon driving. Also, the ohmic contact effect may increase at the contact interface between the contact plug 224 and the lower electrode 202, thereby improving the RESET/SET operation characteristics of the phase-change memory device (I varies inversely with R, R varies inversely with A).

When a contact plug is formed in a cylindrical structure with a straight sidewall, the conductive material forming the contact plug may loosen or break away while subsequent processes are performed or by externally applied physical forces. When the contact plug 224 is formed with the bottom area greater than the top area, the conductive material forming the contact plug 224 may be secured between the interlayer insulating layers 204 and 206, thereby obtaining the additional effect of reducing or preventing the conductive material from loosening or breaking away.

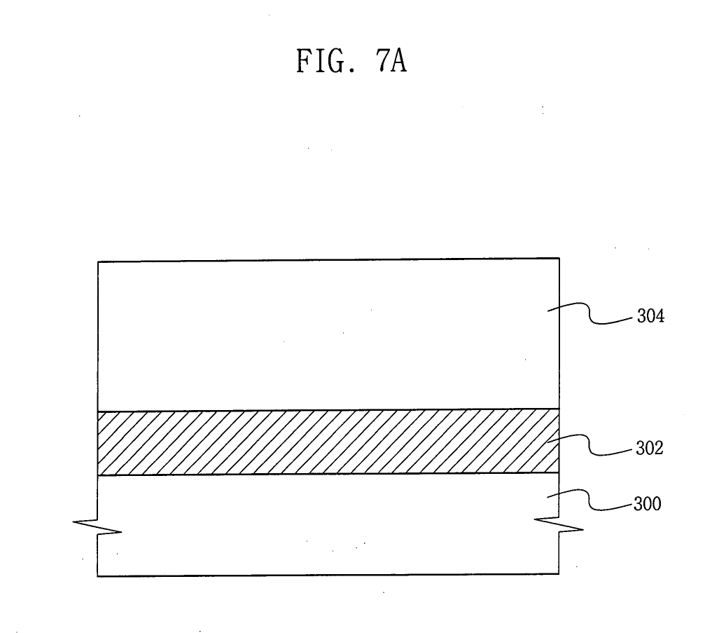

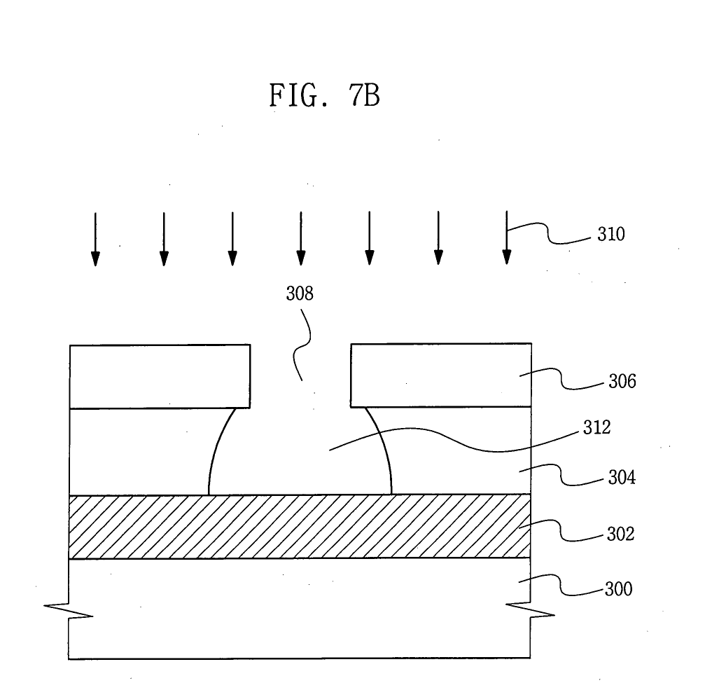

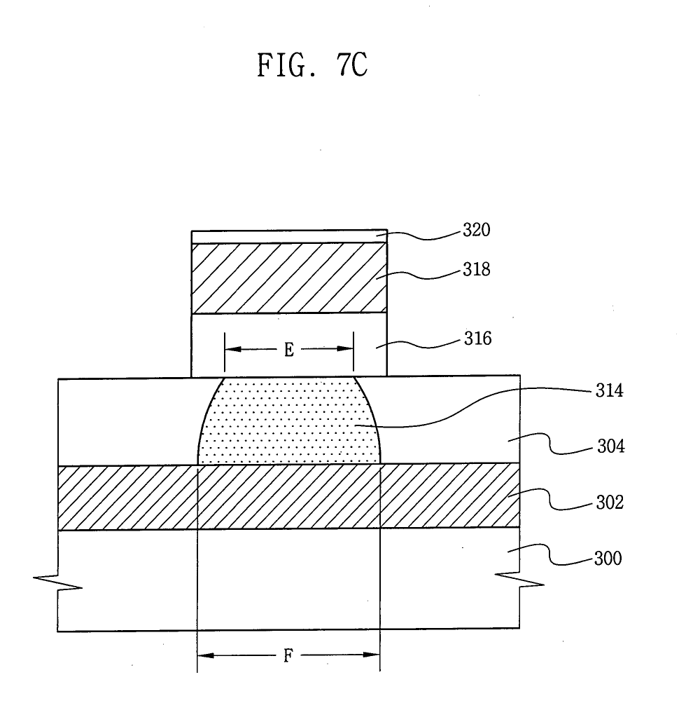

FIGS. 7A-7C are diagrams sequentially illustrating sectional views of a method of fabricating a phase-change memory device according to example embodiments. The phase-change memory device of FIGS. 7A-7C is different from the phase-change memory device of FIGS. 6A-6H, in terms of a structure of a contact plug and a method of fabricating the same. The constituents other than the contact plug of FIGS. 7A-7C are described with reference to FIGS. 6A-6H.

In FIG. 7A, a lower electrode 302 may be formed on a p-type semiconductor substrate 300 doped with Group III impurities, e.g., boron (B) and/or a n-type semiconductor substrate doped with Group V impurities, e.g., phosphorus (P) and/or arsenic (As). The lower electrode 302 may be formed of, for example, a tungsten layer. An interlayer insulating layer 304 may be deposited, with a thickness of about 1000 Å, on the lower electrode 302. The interlayer insulating layer 304 may be composed of an oxide layer including, for example, SiO₂, high temperature oxide (HTO), middle temperature oxide (MTO), middle temperature oxide-nitride-oxide (MTON₂O), TEOS, USG, SOG and/or high density plasma oxide (HDPO) and/or a nitride layer, for example, Si₃N₄.

According to pressure, temperature, applied energy and air pressure, the interlayer insulating layer 304 may be deposited by an atmospheric pressure chemical vapor deposition (APCVD) process performed under an atmospheric pressure, a low pressure chemical vapor deposition (LPCVD) process performed under a low pressure and/or a plasma enhanced chemical vapor deposition (PECVD) process performed under a plasma ambient.

In FIG. 7B, a photo mask pattern 306 may be formed on the interlayer insulating layer 304. A horizontal distance of a hole 308 of the photo mask pattern 306 may be formed so as to be narrower than a horizontal distance of the top area of a contact plug to be finally formed. When the horizontal distance of the top area of the contact plug is set at about 50 nm to decrease power consumption upon driving, the hole 308 of the photo mask pattern 306 may be formed so as to maintain its horizontal distance less than the horizontal distance of the top area.

A wet etch process 310 may be performed on the interlayer insulating layer 304, using the photo mask pattern 306 as a self-aligned etch mask. As a result, a plug contact hole 312 may be formed, penetrating the interlayer insulating layer 304 and exposing the top surface of the lower electrode 302. The wet etch process 310 may have isotropic etch characteristics. A sidewall profile of the plug contact hole 312 may be represented in a curved shape as shown in FIG. 7B. At the beginning of the wet etch process 310, the etching with respect to the interlayer insulating layer 304 may be stopped by the photo mask pattern 306. The top area of the plug contact hole 312 may be formed so as to be smaller than the bottom area thereof, with respect to their horizontal distances.

In FIG. 7C, after the photo mask pattern 306 is removed, a conductive material may fill the inside of the plug contact hole 312, thereby forming a plug contact 314. The conductive material for filling the inside of the plug contact hole 312 may be doped polysilicon, tungsten, aluminium, tantalum and/or copper. A phase-change material layer 316, an upper electrode 318 and an oxide layer 320 may be deposited, in turn, on the plug contact 314. The phase-change material layer 316 may be composed of one material selected from the group including Ge, Sb, Te, Se, Bi, Pb, Sn, As, S, Si, P, O and/or a mixture or alloy thereof. For example, a chalcogenide compound (GST or Ge—Sb—Te) including germanium (Ge), antimony (Sb) and tellurium (Te) may be used as the phase-change material.

In addition to the GST, other chalcogenide compounds that may be used as the phase-change material are As—Sb—Te, As—Gb—Te, As—Gb—Sb—Te, Sn—Sn—Te, In—Sn—Sn—Te, Ag—In—Sb—Te, Group VA element (Ta, Nb, V)—Sb—Te, Group VB element (Ta, Nb, V)—Sb—Se, Group VIB element (W, Mo, Cr)—Sb—Te and/or Group VIB element (W, Mo, Cr)—Sb—Se. The compounds may also include nitrogen. The upper electrode 318 may be composed of a conductive material including nitrogen, metal, dual layer of metal and metallic silicide, alloy, metallic oxynitride and/or a conductive carbon compound. For example, the upper electrode 318 may be composed of a conductive material including a nitrogen element (e.g., TiN, TaN, WN, MoN, NbN, TiSiN, TiAIN, TiBN, ZrSiN, WSiN, WBN, ZrAIN, MoSiN, MoAIN, TaSiN and/or TaAIN) and/or a conductive material layer including any one selected from the group including Ti, W, Mo, Ta, TiSi, TaSi, TiW, TiON, TiAION, WON, TaON and/or a combination thereof. The oxide layer 320 may be composed of SiO₂, HTO, MTO, MTON₂O, TEOS, USG, SOG and/or HDPO.

Although not shown, a capping layer and a via contact for connecting the bit line may be formed on the resultant structure, and a metallization process may be performed, thereby completing the phase-change memory device. As described above, when the plug contact 314 is formed in the manner that the horizontal distance F of the bottom area of the plug contact 314 is relatively greater than the horizontal distance E of the top area thereof, the electrical characteristics of the phase-change memory device may be improved.

When the current is applied to the phase-change material layer 316, the contact interface (about 50 nm or less) between the top area of the plug contact 314 and the phase-change material layer 316 may be smaller, thereby decreasing the power consumption upon driving. Also, the ohmic contact (resistive contact) may be improved at the contact interface (about 50 nm or more) between the bottom area of the contact plug 314 and the lower electrode 302, thereby improving the RESET/SET operational characteristics of the phase-change memory device.

In example embodiments, the contact plug for supplying current to the phase-change material layer may be formed in a manner that the bottom area of the contact plug contacting the lower electrode is greater than the top area of the contact plug contacting the phase-change material layer. As a result, a higher current density may be achieved with respect to the phase-change material layer, thereby reducing or minimizing, the power consumption upon driving. As the contact interface between the bottom area of the contact plug and the lower electrode increases, the ohmic contact effect may be improved, thereby improving the RESET/SET operation characteristics of the phase-change memory device.

The structural feature of the contact plug with the bottom area being greater than the top area may result in the additional effect of preventing or retarding the conductive material forming the contact plug from loosening or breaking away by subsequent processes or external physical forces.

The foregoing is illustrative of the example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope defined in the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A phase-change memory device comprising:
a lower electrode on a semiconductor substrate;
a phase-change material layer on the lower electrode;
a contact plug between the lower electrode and the phase-change material layer, wherein a first area of the contact plug in contact with a top of the lower electrode is greater than a second area of the contact plug in contact with a bottom of the phase-change material layer; and
an upper electrode on the phase-change material layer.

2. The device according to claim 1, wherein the contact plug comprises:
a first contact region provided above the lower electrode; and
a second contact region provided above the first contact region and wherein a second width of the second contact region is smaller than a first width of the first contact region.

3. The device according to claim 2, wherein the first contact region is surrounded by a first interlayer insulating layer, and the second contact region is surrounded by a second interlayer insulating layer.

4. The device according to claim 1, wherein the contact plug has curved sides, a conical shape or a bottle-like shape.

5. The device according to claim 1, wherein the contact plug includes a tiered or step structure having a top tier sectional area that is smaller than a bottom tier sectional area.

6. The device according to claim 1, wherein the sectional structure of the contact plug has a double-spacer or trapezoidal shape, and wherein a first horizontal distance of a bottom area in contact with the lower electrode is greater than a second horizontal distance of a top area in contact with the phase-change material layer.

7. A method of fabricating a phase-change memory device, comprising:
forming a lower electrode on a semiconductor substrate;
forming an interlayer insulating layer on the lower electrode;
forming a contact plug surrounded by the interlayer insulating layer, wherein a bottom sectional area of the contact plug is greater than a top sectional area of the contact plug; and
forming a phase-change material layer and an upper electrode on the contact plug.

8. The method according to claim 7, wherein forming the contact plug includes:
forming an etch mask pattern on the interlayer insulating layer;
forming a contact plug hole for exposing the lower electrode, by performing an etch process with respect to the interlayer insulating layer exposed by the etch mask pattern; and
filling the contact plug hole with a conductive material.

9. The method according to claim 8, wherein the exposed portion of the interlayer insulating layer has a first width that is smaller than a second width of the bottom area of the contact plug hole.

10. The method according to claim 8, wherein the etch process is an isotropic etch process.

11. The method according to claim 7, wherein forming the interlayer insulating layer includes depositing a first interlayer insulating sub-layer and a second interlayer insulating sub-layer having an etch selectivity with respect to the first interlayer insulating sub-layer, on the lower electrode.

12. The method according to claim 11, further comprising:
forming a first contact hole for exposing the first interlayer insulating sub-layer, by performing a first etch process with respect to the second interlayer insulating sub-layer;
forming a second contact hole for exposing the lower electrode and having a horizontal distance greater than that of the first contact hole, by performing a second etch process with respect to the first interlayer insulating sub-layer exposed by the first contact hole and;
wherein forming the contact plug is for current supply and includes filling the first and second contact holes with a conductive material.

13. The method according to claim 12, wherein the first interlayer insulating sub-layer is deposited with a thickness of about 50 Å˜about 500 Å.

14. The method according to claim 13, wherein the first interlayer insulating sub-layer includes SiO₂, HTO, MTO, MTON₂O, TEOS, USG, SOG, or HDP.

15. The method according to claim 12, wherein the second interlayer insulating sub-layer is a nitride layer, and is formed by depositing with a thickness of about 500 Å˜about 950 Å.

16. The method according to claim 12, wherein the first etch process for forming the first contact hole is a dry etch process having anisotropic etch characteristics.

17. The method according to claim 12, wherein the second etch process for forming the second contact hole is a wet etch process having isotropic etch characteristics.

18. The method according to claim 7, wherein the contact plug is formed by filling the insides of the first and second contact holes with doped polysilicon, tungsten, aluminum, tantalum or copper.

19. The method according to claim 7, wherein the phase-change material layer includes at least one material selected from the group including Ge, Sb, Te, Se, Bi, Pb, Sn, As, S, Si, P, O and an alloy thereof.

20. The method according to claim 19, wherein the phase-change material layer includes at least one selected from the group including Ge—Sb—Te, As—Sb—Te, As—Gb—Te, As—Gb—Sb—Te, Sn—Sn—Te, In—Sn—Sn—Te, Ag—In—Sb—Te, Group VB element-Sb—Te, Group VB element-Sb—Se, Group VIB element-Sb—Te, and Group VIB element —Sb—Se.

21. The method according to claim 7, wherein the phase-change material layer includes a compound having nitrogen.

22. The method according to claim 7, wherein the upper electrode has a conductive material including nitrogen, metal, a dual layer of metal and metallic silicide, alloy, metallic oxynitride or conductive carbon compound.

23. The method according to claim 7, wherein the upper electrode has a conductive material including at least one selected from the group including TiN, TaN, WN, MoN, NbN, TiSiN, TiAIN, TiBN, ZrSiN, WSiN, WBN, ZrAIN, MoSiN, MoAIN, TaSiN, TaAIN, Ti, W, Mo, Ta, TiSi, TaSi, TiW, TiON, TiAION, WON or TaON, or a combination thereof.

24. The method according to claim 12, further comprising:
performing an isotropic etch process using CF₄, NF₃ and O₂ as an etchant, to remove a damaged layer on the surface of the lower electrode, after the second contact hole is formed, wherein the lower electrode is composed of tungsten.
